(19) United States
(12) Patent Application Publication
(10) Pub. No.: US 2026/0087198 A1
(43) Pub. Date: Mar. 26, 2026

(54) SIMULATING ROLL-UP OF GARMENT PART

(71) Applicant: CLO Virtual Fashion Inc., Seoul (KR)

(72) Inventors: Jae Hwan MA, Seoul (KR); Gi Seong YUN, Seoul (KR)

(21) Appl. No.: 19/211,086

(22) Filed: May 16, 2025

Related U.S. Application Data
(63) Continuation of application No. PCT/KR2023/017879, filed on Nov. 8, 2023.

(30) Foreign Application Priority Data
Nov. 18, 2022 (KR) 10-2022-0155197
Nov. 3, 2023 (KR) 10-2023-0150894

(51) Int. Cl. G06F 30/20

(52) U.S. Cl. CPC G06F 30/20

(57) ABSTRACT

A roll-up simulation method and device according to an embodiment determine a base plane corresponding to a target portion of roll-up in three-dimensional (3D) clothes, determine, on the basis of the base plane, target vertices, affected by the roll-up, among vertices corresponding to the target portion, and transform the target vertices into vertices in which the roll-up is reflected, thereby simulating the 3D clothes in which the roll-up is expressed.

### CROSS-REFERENCE TO RELATED APPLICATIONS

This is a bypass continuation of International PCT Application No. PCT/KR2023/017879 filed on Nov. 8, 2023, which claims priority to Republic of Korea Patent Application No. 10-2022-0155197, filed on Nov. 18, 2022, and Republic of Korea Patent Application No. 10-2023-0150894, filed on Nov. 8, 2023, which are incorporated by reference herein in their entirety.

### TECHNICAL FIELD

The embodiments relate to a roll-up simulation method and device.

### BACKGROUND

Clothes appear three dimensions when worn by a person, but they are actually a combination of pieces of fabric cut according to a two-dimensional (2D) pattern. Because fabric, a material of clothes, is flexible, the shape of the fabric may vary depending on the body shape or movement of a person wearing the clothes. In addition, fabric may have various physical properties, such as strength, stretch, and shrinkage, and a difference in each physical property of the fabric may differentiate representation or impression of clothes even though the clothes have the same design.

Despite the wide use of computer-based clothing simulation technology to develop an actual clothes design in the fashion industry, it is not easy to express roll-up, such as rolling up sleeves of clothes or folding up hems of trousers.

### SUMMARY

According to an embodiment, a roll-up simulation method includes receiving an input of a user for a target portion of roll-up in three-dimensional (3D) clothes, determining a base plane corresponding to the target portion of the roll-up, based on the base plane, determining target vertices affected by the roll-up among vertices corresponding to the target portion, transforming the target vertices into vertices in which the roll-up is reflected, and simulating the 3D clothes in which the roll-up is expressed.

The base plane may include a plane passing through an end of the target portion and perpendicular to a direction for the roll-up.

The determining of the base plane may include determining at least one two-dimensional (2D) pattern corresponding to the target portion, determining a base line in the at least one 2D pattern, determining a midpoint of the base line, determining an adjacent point located in a vertical direction from the midpoint into the at least one 2D pattern, and setting an up-vector in a direction from the midpoint to the adjacent point.

The determining of the target vertices may include, based on a fold interval of the roll-up and a number of folds of the roll-up from the base plane, classifying the target portion into each of sections of a fold region of the roll-up and extracting vertices included in each of the sections of the fold region as the target vertices.

The classifying of the target portion into the sections of the fold region may include, according to the fold interval and the number of folds from the base plane, determining a reference section corresponding to the number of folds among the sections of the fold region of roll-up, and the extracting of the vertices as the target vertices may include extracting vertices located below the reference section as the target vertices corresponding to each of the sections of the fold region.

The classifying of the target portion into the sections of the fold region may include, according to the fold interval and the number of folds from the base plane, assigning an index corresponding to the sections of the fold region to the target vertices.

The classifying of the target portion into the sections of the fold region may include classifying the target portion into the sections of the fold region according to a preset formula.

The classifying of the target portion into the sections of the fold region may include setting at least one fold line and a buffer region corresponding to the number of folds and determining the sections of the fold region by reflecting the buffer region in the fold interval.

The setting of the at least one fold line may include re-meshing by moving at least one of locations and particle intervals of the target vertices.

The buffer region may increase as a number of the sections of the fold region increases.

The simulating of the 3D clothes may include transforming the target vertices included in each of the sections of the fold region into the vertices in which the roll-up is reflected.

The transforming of the target vertices into the vertices in which the roll-up is reflected may include defining a virtual plane including at least one of the target vertices and a z-axis perpendicular to the base plane, and transforming at least one of the target vertices into vertices in the virtual plane.

The of the 3D clothes may include simulating the 3D clothes by restoring the transformed vertices to world coordinates corresponding to the 3D clothes.

The defining of the virtual plane may include projecting the target vertices onto the base plane, determining a center point of a bounding box including the target vertices projected onto the base plane, and determining the z-axis based on the center point.

The transforming of the at least one of the target vertices into the vertices in the virtual plane may include calculating a displacement corresponding to the at least one of the target vertices in the virtual plane, based on a height and a width corresponding to the number of folds and the fold interval of the roll-up.

According to another embodiment, a computing device includes at least one processor and a memory configured to store a plurality of instructions, wherein the plurality of instructions, when executed by the at least one processor, may cause the computing device to perform: receiving an input of a user for a target portion of roll-up in 3D clothes, determining a base plane corresponding to the target portion of the roll-up, based on the base plane, determining target vertices affected by the roll-up among vertices corresponding to the target portion, transforming the target vertices into vertices in which the roll-up is reflected, and simulating the 3D clothes in which the roll-up is expressed.

According to an aspect, three-dimensional (3D) clothes may be simulated in which a plurality of roll-ups are expressed according to a fold interval of roll-up and the number of folds of roll-up input by a user.

According to an aspect, 3D clothes in which a plurality of roll-ups is expressed may be expressed without twisting or penetration.

According to an aspect, by reflecting at least one fold line corresponding to the number of folds of roll-up in a mesh of a two-dimensional (2D) pattern and/or 3D clothes, an issue that a folded portion of roll-up becomes uneven due to insufficient mesh resolution may be solved.

According to an aspect, operational complexity may be reduced by performing a simulation using a coarse mesh before re-meshing, instead of a fine mesh, for a portion in which roll-up is not performed in 2D pattern and/or 3D clothes, that is, a reference section that may not be folded.

### BRIEF DESCRIPTION OF THE DRAWINGS

FIG. 1 is a diagram illustrating a basic concept of simulating roll-up, according to an embodiment.

FIG. 2 is a flowchart illustrating a method of simulating roll-up, according to an embodiment.

FIG. 3 is a diagram illustrating a method of determining a base line, according to an embodiment.

FIG. 4 is a flowchart illustrating a method of determining target vertices, according to an embodiment.

FIG. 5 is a flowchart illustrating a method of classifying sections of a fold region, according to an embodiment.

FIGS. 6A and 6B are diagrams illustrating a method of setting a buffer region, according to an embodiment.

FIG. 7 is a diagram illustrating a method of classifying sections of a fold region, according to an embodiment.

FIG. 8 is a flowchart illustrating a method of simulating three-dimensional (3D) clothes, according to an embodiment.

FIG. 9 is a diagram illustrating a method of defining a virtual plane, according to an embodiment.

FIG. 10 is a flowchart illustrating a method of transforming target vertices into vertices in a virtual plane, according to an embodiment.

FIG. 11 is a diagram illustrating a result of re-meshing vertices transformed into a virtual plane, according to an embodiment.

FIG. 12 is a diagram illustrating a process of performing a roll-up simulation through a user interface, according to an embodiment.

FIG. 13 is a flowchart illustrating a method of simulating roll-up, according to an embodiment.

FIG. 14 is a block diagram illustrating a device for simulating roll-up, according to an embodiment.

### DETAILED DESCRIPTION

Hereinafter, embodiments will be described in detail with reference to the accompanying drawings. However, various alterations and modifications may be made to the embodiments, and thus, the embodiments are not construed as limiting the scope of the rights of the patent application. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components regardless of drawing numbers and a repeated description related thereto will be omitted. In the description of embodiments, detailed description of well-known related technology will be omitted when it is deemed that such description will cause ambiguous interpretation of the present disclosure.

Also, in the description of the components of the embodiments, terms such as first, second, A, B, (a), (b), and the like may be used. These terms are used only for the purpose of discriminating one component from another component, and the nature, the sequences, or the orders of the components are not limited by the terms. When one component is described as being “connected”, “coupled”, or “attached” to another component, it should be understood that one component may be connected or attached directly to another component, and an intervening component may also be “connected”, “coupled”, or “attached” to the components.

The same name may be used to describe an element included in the embodiments described above and an element having a common function. Unless otherwise mentioned, the descriptions of the embodiments may be applicable to the following embodiments and thus, duplicated descriptions will be omitted for conciseness.

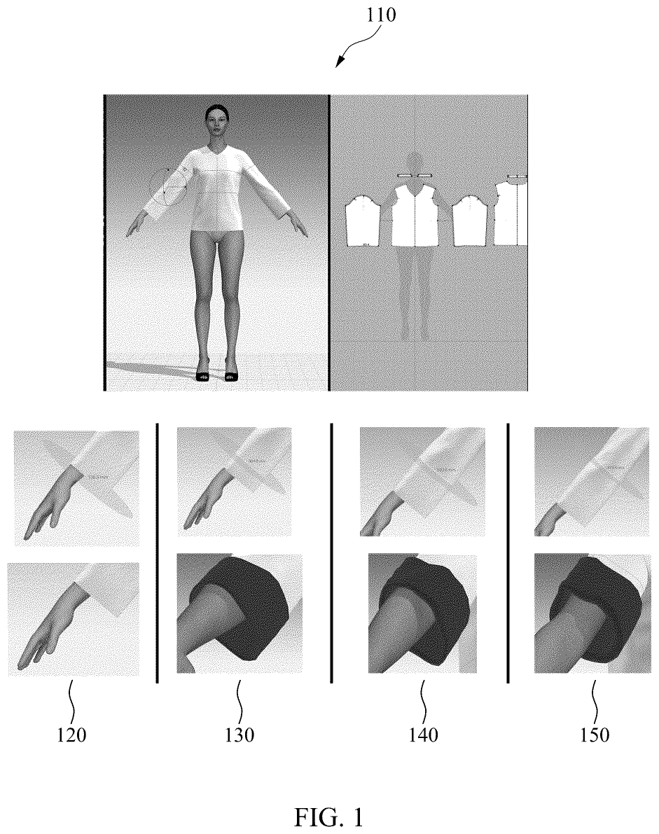

FIG. 1 is a diagram illustrating a basic concept of simulating roll-up, according to an embodiment. Referring to FIG. 1, according to an embodiment, a screen 110 in which a target portion (e.g., a sleeve portion) to be rolled up by a user is selected in three-dimensional (3D) clothes and diagrams 120, 130, 140, and 150 representing results of simulating roll-up from 0 to 3 times in the target portion selected by the user are illustrated.

The “roll-up” may refer to turn up a portion of clothes or to fold clothes several times. The target portion of clothes to be rolled up may be, for example, sleeves and/or hems of trousers.

As shown in the screen 110, the target portion (e.g., the sleeve portion) on which roll-up is to be performed in the 3D clothes may be selected by a mouse click or the like. In this case, according to an embodiment, a simulation device may provide a user interface for receiving, as input, a fold interval of roll-up and/or the number of folds of roll-up corresponding to the target portion selected by the user to express the roll-up. The “fold interval of roll-up” may be a value representing an interval (length or height) at which the roll-up is to be performed and may be set, for example, in units of 5 millimeters (mm) or 1 centimeter (cm), but the embodiment is not necessarily limited thereto. The “number of folds of roll-up” may be a value representing how many times the roll-up is to be performed or in other words, how many times the clothes are to be folded and may be set, for example, to any value from 1 to 3 times, but the embodiment is not necessarily limited thereto.

The number of folds of roll-up and/or the fold interval of roll-up may be input by the user through the user interface or may be provided with a default value in advance without separate input.

Depending on embodiments, the simulation device may receive a pattern, rather than the 3D clothes, selected by the user to be rolled-up from among two-dimensional (2D) patterns that include the 3D clothes. For example, the simulation device may provide the roll-up by having the user click on an outline (or an outline of the 2D patterns) of the 3D clothes and then right-click (or left-click) a mouse to select a roll-up function. When the roll-up function is selected, the simulation device may display the user interface or a pop-up menu on the screen to set the fold interval of roll-up and/or the number of folds of roll-up. The simulation device may display the results of simulating the roll-up on the sleeves, as shown in the diagrams 120, 130, 140, and 150, according to the fold interval of roll-up and the number of folds of roll-up input or set through the pop-up menu.

The diagram 120 may represent a sleeve in a state where the roll-up function is not applied. The diagram 130 may represent, for example, a simulation result when the fold interval of roll-up is approximately 30 mm and the number of folds of roll-up is set to 1. The diagram 140 may represent, for example, a simulation result when the fold interval of roll-up is approximately 50 mm and the number of folds of roll-up is set to 2. The diagram 150 may represent, for example, a simulation result when the fold interval of roll-up is approximately 70 mm and the number of folds of roll-up is set to 3.

According to an embodiment, the simulation device may automatically express the roll-up on the selected portion of the 3D clothes according to a preset fold interval of roll-up and/or number of folds of roll-up, without separate input from the user, as the roll-up function is selected on the target portion of the 3D clothes or the target portion of the 2D patterns.

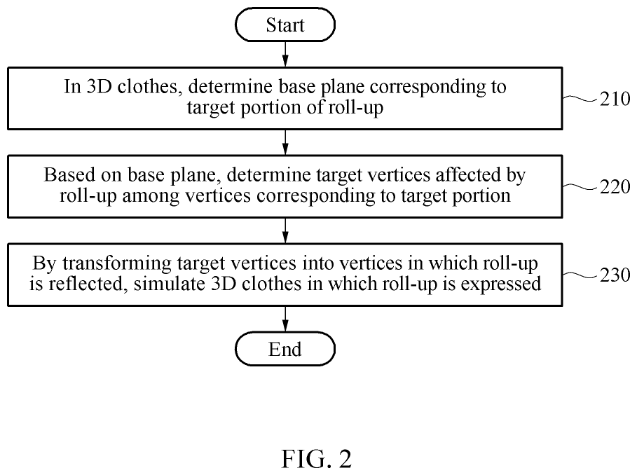

FIG. 2 is a flowchart illustrating a method of simulating roll-up, according to an embodiment. Operations to be described with reference to FIG. 2 and below may be performed sequentially but not necessarily. For example, the order of the operations may change and at least two of the operations may be performed in parallel.

Referring to FIG. 2, according to an embodiment, a roll-up simulation device (hereinafter, “a simulation device”) may simulate 3D clothes in which roll-up is expressed, through operations 210 to 230.

In operation 210, the simulation device may determine a base plane and/or a base line corresponding to a target portion selected to be rolled-up by a user in the 3D clothes. The base plane may correspond to a bottom surface (e.g., the diagram 120 of FIG. 1) of a virtual cylinder defined based on the target portion to be rolled-up. The base line may correspond to an outline of a 3D clothes portion corresponding to the base plane.

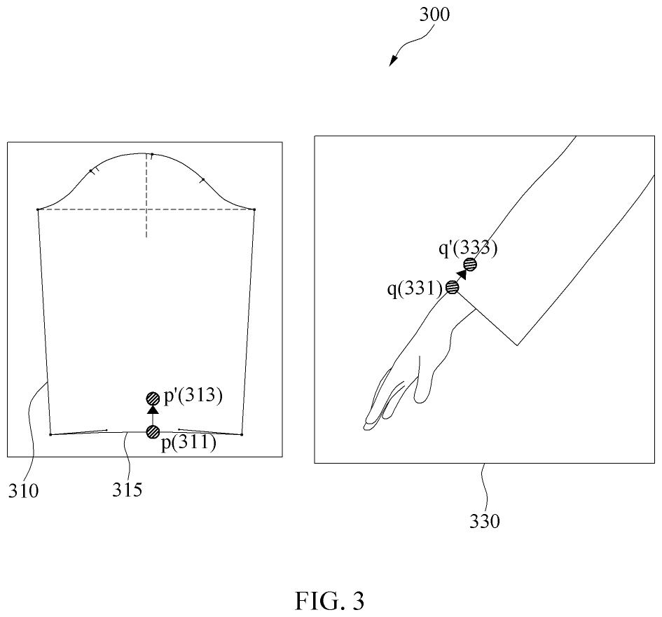

The simulation device may determine a midpoint at a location where the distance from both end points of an end (e.g., an end of sleeves or trousers) of the target portion (e.g., sleeves or trousers) selected by the user from among the 2D patterns corresponding to the 3D clothes is the same. The simulation device may determine an adjacent point located in a vertical direction from the midpoint into the corresponding 2D pattern (e.g., a sleeve pattern or a trouser pattern). The simulation device may determine the base line in the 3D clothes by setting an up-vector in a direction from the midpoint to the adjacent point located at an upper portion. The method of determining the base line by the simulation device is described in more detail with reference to FIG. 3 below.

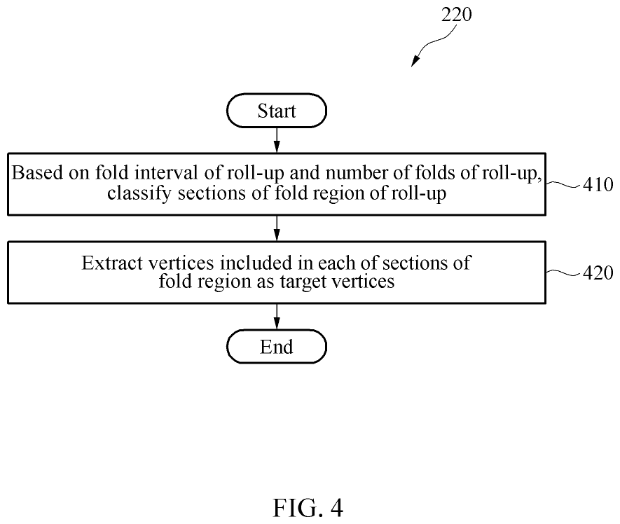

In operation 220, based on the base plane and/or the base line determined in operation 210, the simulation device may determine target vertices affected by the roll-up among vertices corresponding to the target portion. In the present specification, the “vertices” may refer to vertices of polygons (e.g., triangles) included in a mesh of the 2D patterns and/or the 3D clothes. In addition, the “target vertices” may refer to vertices in a region affected by the roll-up among the vertices of the polygons (e.g., triangles) included in the mesh of the 2D patterns and/or the 3D clothes. The method of determining the target vertices by the simulation device is described in more detail with reference to FIGS. 4 to 7 below.

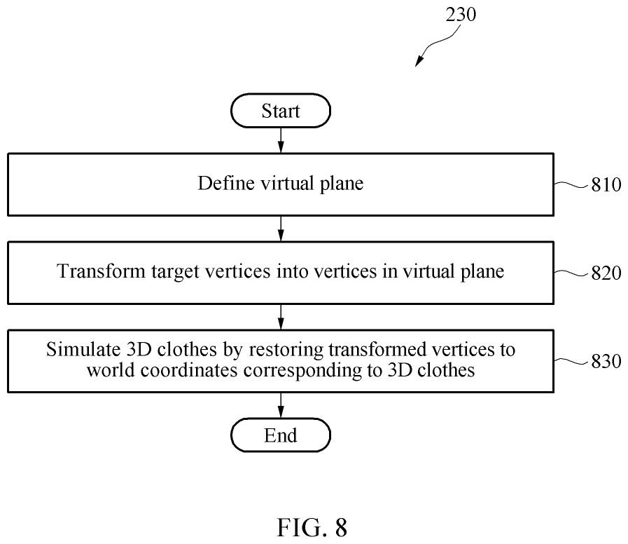

In operation 230, by transforming the target vertices determined in operation 220 into vertices in which the roll-up is reflected, the simulation device may simulate the 3D clothes in which the roll-up is expressed. As will be described in more detail below, when a region in which height and width are expanded is determined as sections of a fold region by reflecting a buffer region in a fold interval, the simulation device may transform the target vertices included in each of the sections of the fold region determined by the region in which height and width are expanded into the vertices in which the roll-up is reflected. For example, the simulation device may project the target vertices onto each of base planes and by moving the target vertices based on a center point of a bounding box including the target vertices projected onto each of the base planes, may transform the target vertices into the vertices in the virtual plane. The simulation device may simulate the 3D clothes by restoring the transformed vertices to world coordinates corresponding to the 3D clothes. The method of simulating the 3D clothes by the simulation device is described in more detail with reference to FIGS. 8 to 1 below.

FIG. 3 is a diagram illustrating a method of determining a base line, according to an embodiment. Referring to FIG. 3, according to an embodiment, a diagram 300 showing a 2D pattern 310 of a sleeve portion determined as a target of roll-up from among 2D patterns corresponding to 3D clothes and a sleeve portion 330 of 3D clothes is illustrated.

In the present specification, the 2D pattern(s) may be 2D pattern(s) that is virtually produced by a computer program. The 2D pattern(s) may be, for example, patterns of 3D clothes that the user desires to produce. The 2D pattern(s) may be virtual 2D clothes patterns modeled as a sum of meshes of numerous polygons (e.g., triangles) to simulate the 3D virtual clothes. For example, when the polygons are triangles, three vertices of a mesh may be points having mass (point mass), and each side of the mesh may be represented as springs having elasticity that connects the mass. The 2D pattern(s) may be modeled by a mass-spring model, for example. Here, the springs may have respective resistance values against, for example, stretch, shear, and bending, depending on a material property of fabric used. Each vertex may move according to the action of an external force such as gravity and the action of an internal force such as stretch, shear, and bending. When a force being applied to each vertex is obtained by calculating the external force and the internal force, the speed of movement and displacement of each vertex may be obtained. In addition, a motion of the virtual clothes may be simulated through a motion of the vertices of the meshes in each time step. By draping the 2D patterns formed with triangle meshes over a 3D avatar, it may be possible to embody 3D virtual clothes that looks natural based on the laws of physics.

A simulation device may determine at least one 2D pattern corresponding to a target portion of roll-up among 2D patterns corresponding to 3D clothes, based on input of a target portion selected by the user. Here, the target portion may correspond to, for example, an end of the 2D pattern 310 of the sleeve portion.

When the target portion on which roll-up is to be performed is selected through user input, the simulation device may define a base plane to be a bottom surface of a virtual cylinder based on the selected target portion, and may perform a roll-up simulation by a virtual plane defined based on the base plane.

For example, the simulation device may determine a midpoint p 311 at the end of the 2D pattern 310 of the sleeve portion. The simulation device may determine an adjacent point p′ 313 located in a vertical direction from the midpoint p 311 into the 2D pattern 310 of the sleeve portion. The simulation device may obtain the adjacent point p′ 313, for example, spaced apart by a predetermined distance from the midpoint p 311 in the direction perpendicular to a straight line connecting a start point to an end point by 90 degrees at the end (a sleeve end) of the 2D pattern 310 of the sleeve portion. The simulation device may determine a base plane and/or a base line in a 3D window by setting an up-vector from the midpoint p 311 toward the adjacent point p′ 313. Here, in the sleeve portion 330 of the 3D clothes, when 3D coordinates corresponding to the midpoint p 311 and the adjacent point p′ 313 are q 331 and q′ 333, respectively, q′−q may be an up-vector direction.

As described above, when user input for the target portion is received through a 2D window in which the 2D patterns are displayed, the simulation device may display the base line 315 corresponding to the user input in the 3D window in which the 3D clothes are displayed and may perform a process of generating the virtual plane in which roll-up is implemented.

FIG. 4 is a flowchart illustrating a method of determining target vertices, according to an embodiment. Referring to FIG. 4, according to an embodiment, a simulation device may extract target vertices through operations 410 and 420.

In operation 410, based on a fold interval of roll-up and the number of folds of roll-up from a base plane and/or a base line, the simulation device may classify each of sections of a fold region of roll-up in at least one 2D pattern and/or 3D clothes. For example, the simulation device may classify the sections of the fold region according to a preset formula (e.g., (the number of folds of roll-up n×2)+1=the number of the sections of the fold region) in response to the number of folds (n=2). For example, the sections of the fold region may be classified into regions of (the number of folds of roll-up n×2)+1=5. According to the fold interval and the number of folds from the base line, the simulation device may assign indices corresponding to the sections of the fold region to the target vertices.

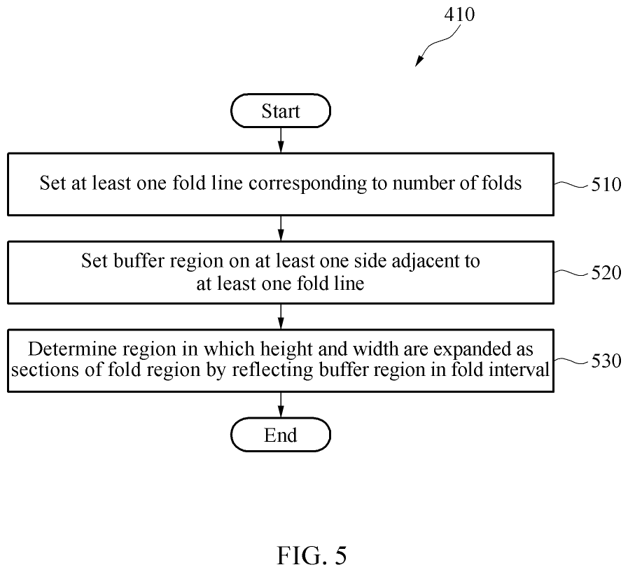

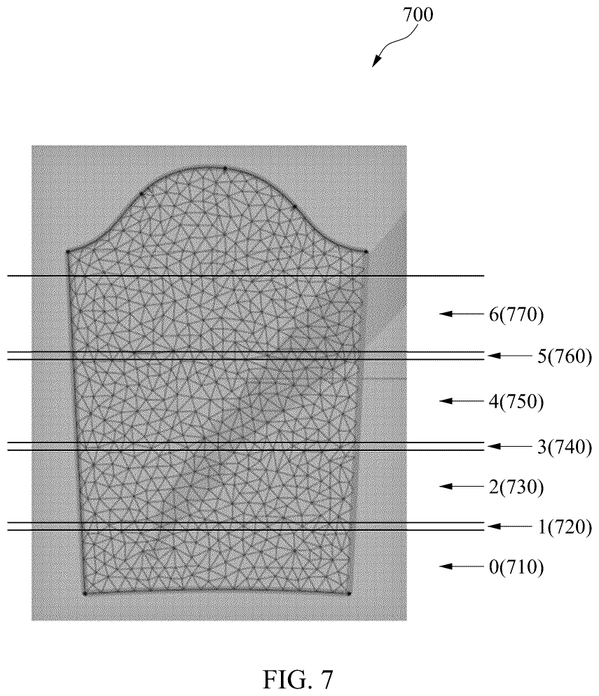

In addition, for example, according to the fold interval and the number of folds from the base plane and/or the base line, the simulation device may determine a reference section corresponding to the number of folds among the sections of the fold region of roll-up. The “reference section” may correspond to an uppermost section or region that serves as a support for portions rolled-up from the bottom of a target portion of roll-up, although there is no location change of actual vertices. The location of the reference section may change depending on the number of folds. For example, as the number of folds of roll-up increases, the location of the reference section may also gradually increase. For example, when the number of folds is 1, the reference section may correspond to a section (e.g., a section 2 730 of FIG. 7) facing a roll-up portion folded outward once according to the fold interval. In addition, when the number of folds is 2, the reference section may correspond to a section (e.g., a section 4 750 of FIG. 7) facing a roll-up portion folded twice according to the fold interval. The method of classifying each of the sections of the fold region by the simulation device is described in more detail with reference to FIG. 5 below.

In operation 420, the simulation device may extract vertices included in each of the sections of the fold region as the target vertices. For example, when the reference section corresponding to the number of folds of roll-up is determined, the simulation device may extract vertices located below the reference section as the target vertices corresponding to each of the sections of the fold region.

FIG. 5 is a flowchart illustrating a method of classifying sections of a fold region, according to an embodiment.

Referring to FIG. 5, according to an embodiment, a simulation device may classify the sections of the fold region through operations 510 to 530.

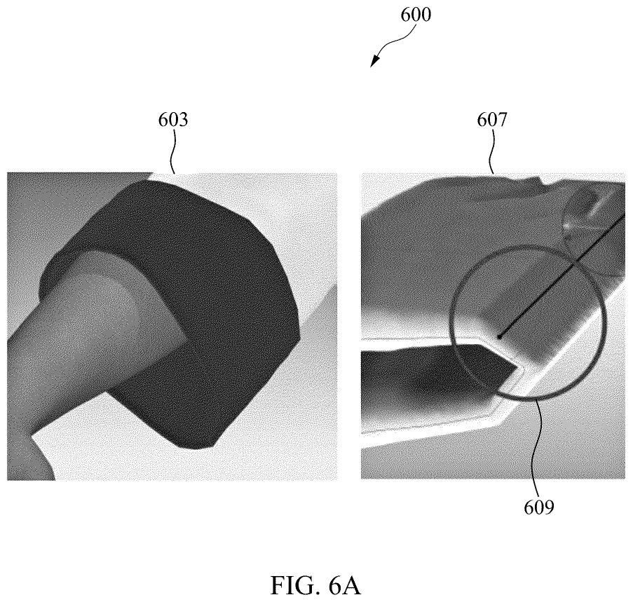

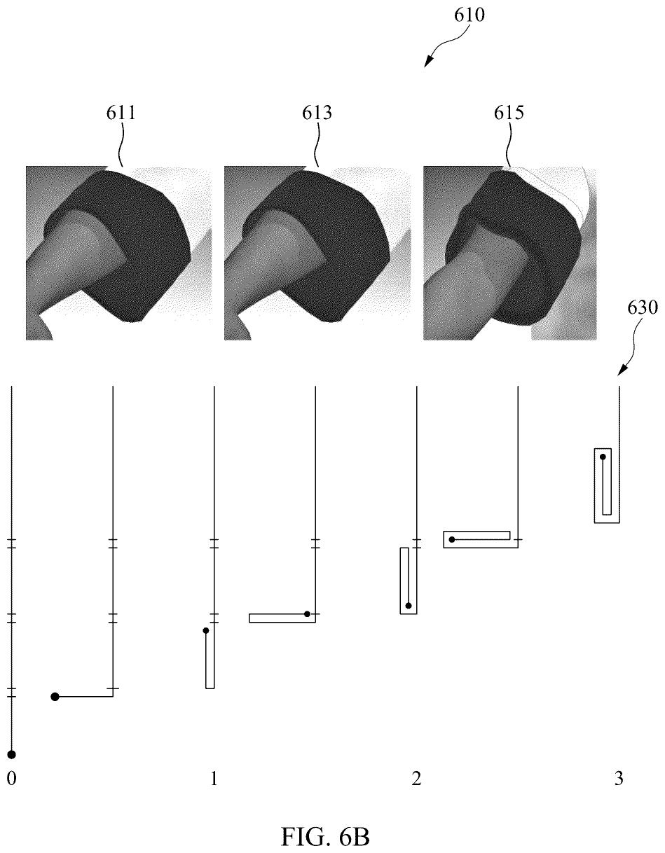

In operation 510, the simulation device may set at least one fold line corresponding to the number of folds in at least one 2D pattern and/or 3D clothes. For example, the simulation device may perform re-meshing by moving at least one of locations and particle intervals of the target vertices so that the at least one fold line is reflected in a mesh of the at least one 2D pattern and/or 3D clothes. Here, the “re-meshing” may be understood as a process of moving the location and interval of a polygon (e.g., a triangle) of the mesh, when setting two fold lines that fold in a flattened “U” shape, to match the fold lines so that the polygon is not separated by the fold lines, as shown in FIG. 6A below.

In operation 520, the simulation device may set a buffer region on at least one side adjacent to the at least one fold line set in operation 510. The buffer region may be increased cumulatively in proportion to the number of the sections of the fold region increasing. The method of setting the buffer region by the simulation device is described in more detail with reference to FIGS. 6A and 6B below.

In operation 530, the simulation device may determine a region in which height and width are expanded as the sections of the fold region by reflecting the buffer region set in operation 520 in a fold interval. The method of determining the sections of the fold region by the simulation device is described in more detail with reference to FIG. 7 below.

FIGS. 6A and 6B are diagrams illustrating a method of setting a buffer region, according to an embodiment.

Referring to FIG. 6A, according to an embodiment, a diagram 600 including a diagram 603 showing 3D clothes in which a sleeve portion folded by roll-up is expressed and a diagram 607 showing the enlarged sleeve portion folded by roll-up is illustrated.

For example, when a sleeve of clothes is rolled-up using one fold line, a folded surface of roll-up is folded in a sharp “V” shape, and thus, vertices near the fold line may become twisted or overlap each other. Particularly, when the number of folds of roll-up is 2 or more, a rolled-up portion may be layered over the clothes. As such, when roll-up of the sleeve is simulated using only one fold line, the thickness of the rolled-up portion may not only faithfully reflected, but locations of vertices of a folded portion may overlap each other or penetrate the clothes, and thus, the roll-up simulation may not performed properly.

In an embodiment, with respect to at least one fold line corresponding to the number of folds, by setting a small buffer region on both sides or at least one side of the fold line, the folded portion may be formed to have a flattened “U” shape as shown in a diagram 609. For example, when the number of folds is 1, a simulation device may set three fold lines corresponding to the number of folds of 1 so that a fold region including the buffer region becomes a flattened “U” shape.

Referring to FIG. 6B, according to an embodiment, a diagram 610 showing sleeve portions 611, 613, and 615 of 3D clothes with an increased number of folds of roll-up and a diagram 630 showing the number of fold lines and the buffer region that gradually increase as the number of folds of roll-up increases are illustrated. The numbers (e.g., 0 to 3) written at the bottom of the diagram 630 may represent the number of folds of roll-up.

For example, in the diagram 610, the sleeve portion 611 may represent a case where the number of folds of roll-up is 1. The sleeve portion 613 may represent a case where the number of folds of roll-up is 2. The sleeve portion 615 may represent a case where the number of folds of roll-up is 3.

The simulation device may set the buffer region so that both a fold thickness and a fold-up length in the diagram 630 gradually increase as the number of folds of roll-up increases. The simulation device may cumulatively increase the buffer region as the number of folds of roll-up increases, thereby maintaining the shape of a portion where the roll-up is expressed even during the simulation and allowing natural draping.

FIG. 7 is a diagram illustrating a method of classifying sections of a fold region, according to an embodiment. Referring to FIG. 7, according to an embodiment, a 2D sleeve pattern 700 is illustrated in which a fold region of roll-up is classified into seven sections 710, 720, 730, 740, 750, 760, and 770, respectively, when the number of folds of roll-up is 3.

A simulation device may classify sections of the fold region of roll-up in the 2D sleeve pattern 700, based on a fold interval of roll-up and the number of folds of roll-up from a base line corresponding to a bottom surface of the 2D sleeve pattern 700. Here, for example, based on a height from a base plane corresponding to the number of folds of roll-up, the simulation device may extract a set V of vertices affected by the roll-up and may classify the vertices into the sections.

According to an embodiment, the simulation device may set a roll-up state in which the fold interval of roll-up is 50 mm, the number of folds of roll-up is 3, and a buffer region is 5 mm. In this case, in response to the number of folds (n=3), the simulation device may confirm seven sections of the fold region ((the number of folds of roll-up (n=3)×2)+1=7). The 2D sleeve pattern 700 may be classified into a total of seven regions from the section 0 710 to the section 6 770. Here, the length and width of each of the sections may be determined as the length and width reflecting the buffer region. The length and width of the buffer region may increase cumulatively each time the roll-up is performed. As the number of folds of roll-up increases, both a fold thickness and a fold-up length in the buffer region may be gradually increased.

According to the fold interval and the number of folds from the base line, the simulation device may determine a reference section corresponding to the number of folds among the sections of the fold region of roll-up and may extract vertices included in each of the sections of the fold region as target vertices corresponding to each base plane.

For example, the simulation device may determine a length of the section 0 710 by considering the buffer region. In this case, the simulation device may calculate the length of the section 0 710 as a difference (e.g., 45 mm) between the fold interval of roll-up (e.g., 50 mm) and the buffer region (e.g., 5 mm).

The section 1 720 may correspond to the buffer region. A length of the section 1 720 may be 5 mm. Therefore, the total length from the section 0 710 to the section 1 720 may be 50 mm.

According to an embodiment, a length of the section 2 730 may be 50 mm, which is 5 mm longer than the length of the section 0 710. Therefore, a total length from the section 0 710 to the section 2 730 may correspond to a sum (e.g., 100 mm) of a total length (e.g., 50 mm) from a bottom surface of the section 0 710 to the section 1 720 and the length (e.g., 50 mm) of the section 2 730.

The section 3 740 may correspond to the buffer region. A length of the section 3 740 may be 10 mm, which is 5 mm longer than the length of the section 1 720. A total length from the section 0 710 to the section 3 740 may be a sum (e.g., 110 mm) of a total length (e.g., 100 mm) from the bottom surface of the section 0 710 to the section 2 730 and the length (e.g., 10 mm) of the section 3 740. Here, since the section 3 740 is rolled-up once, the height/width of the buffer region may each be additionally increased by 5 mm.

A length of the section 4 750 may be 55 mm, which is 5 mm longer than the length of the section 2 730. A total length from the section 0 710 to the section 4 750 may be a sum (e.g., 165 mm) of a total length (e.g., 110 mm) from the bottom surface of the section 0 710 to the section 3 740 and the length (e.g., 55 mm) of the section 4 750.

The section 5 760 may correspond to the buffer region. A length of the section 5 760 may be 15 mm, which is 5 mm longer than the length of the section 3 740. A total length from the section 0 710 to the section 5 760 may be a sum (e.g., 180 mm) of a total length (e.g., 165 mm) from the bottom surface of the section 0 710 to the section 4 750 and the length (e.g., 15 mm) of the section 5 760.

A total length from the section 0 710 to the section 6 770 may be a sum (e.g., 255 mm) of a total length (e.g., 180 mm) from the section 0 710 to the section 5 760 and a length (e.g., 75 mm) of the section 6 770. Here, the length (e.g., 75 mm) of the section 6 770 may be an upper limit of actual fold regions, which may be stacked, and may be, for example, 1.5 times the height input by a user, that is, the fold interval of roll-up (e.g., 50 mm). However, embodiments are not necessarily limited thereto.

The section 6 770 may be the reference section, for example, when the number of folds of roll-up is 3. The section 6 770 may not be a section that is actually folded during the roll-up, but rather a section that supports the folded sections, in other words, the reference section on which six sections from the section 0 710 to the section 5 760 are stacked. The reference section may also be referred to as a “support section” in that the reference section serves as a support for lower sections of the fold region, although there is no location change of actual vertices.

The simulation device may assign indices corresponding to the sections of the fold region to the target vertices included in each section, based on the height from the bottom surface of the section 0 710 (e.g., the fold interval of roll-up input by the user). For example, indices of odd-numbers, such as an index 1 corresponding to the section 1 720, an index 3 corresponding to the section 3 740, and an index 5 corresponding to the section 5 760, may represent buffer regions.

FIG. 8 is a flowchart illustrating a method of simulating 3D clothes, according to an embodiment. Referring to FIG. 8, according to an embodiment, a simulation device may simulate 3D clothes through operations 810 to 830.

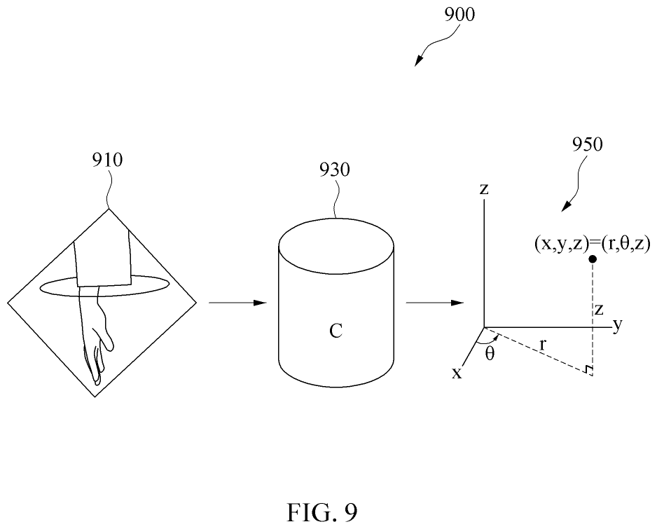

In operation 810, the simulation device may define a virtual plane. For example, based on an up-vector of a target portion, the simulation device may define a base plane of a virtual cylinder. The simulation device may define the virtual plane corresponding to the arbitrary first vertex in the 3D clothes. In a roll-up process, since theta may be fixed as a constant, wherein the theta corresponds to an angle among components of cylindrical coordinates, the corresponding vertices may be moved within an RZ plane of the virtual plane. The method of defining the virtual plane by the simulation device is described in more detail with reference to FIG. 9 below.

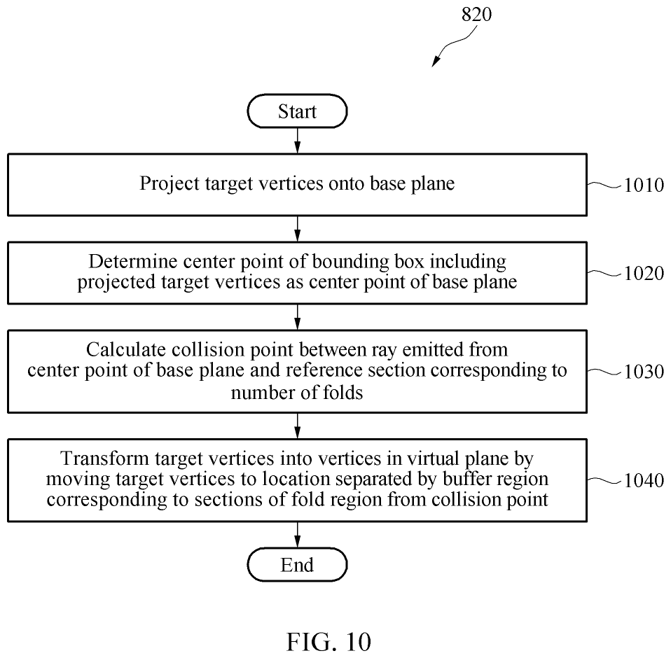

In operation 820, the simulation device may transform the target vertices determined in operation 220 into vertices in the virtual plane defined in operation 810. The simulation device may transform all vertices in a set V of vertices affected by roll-up into the vertices in a corresponding local RZ plane. The method of transforming the target vertices into the vertices in the virtual plane by the simulation device is described in more detail with reference to FIG. 10 below.

In operation 830, the simulation device may simulate the 3D clothes by restoring the vertices transformed in operation 820 to world coordinates corresponding to the 3D clothes. For example, by adjusting and re-meshing at least one of locations and intervals of the transformed vertices included in each of sections of a fold region, the simulation device may restore the transformed vertices to the world coordinates corresponding to the 3D clothes.

FIG. 9 is a diagram illustrating a method of defining a virtual plane, according to an embodiment. Referring to FIG. 9, according to an embodiment, a diagram 900 showing a sleeve portion 910 to be rolled-up selected by a user in 3D clothes, a base plane defined as a lower surface of a cylinder 930 corresponding to the sleeve portion 910, and a cylindrical coordinate system 950 reflecting the cylinder 930 is illustrated. For example, based on an arbitrary vertex P on an end of the sleeve portion 910, which is a target portion selected by the user, and the above-described up-vector V, the simulation device may define a base plane of a virtual cylinder. For example, when a sleeve is wrinkled, the base plane generated corresponding to an end of the wrinkled sleeve may not be a bottom surface of the cylinder. Here, since the vertex P is an arbitrary point on a 2D pattern, a location of a vertex P′ corresponding to the vertex P in the 3D clothes may be below the base plane. Accordingly, the simulation device may move the base plane based on a distance between a second vertex (e.g., the vertex P′) corresponding to the arbitrary first vertex (e.g., the vertex P) in the 3D clothes and the base plane.

More specifically, the simulation device may obtain a distance (e.g., a signed distance) between the second vertex (e.g., the vertex P′) and the base plane so that the base plane becomes the bottom surface in actual 3D clothes. Here, when locations of vertices are above the base plane, the signed distance may be “+”, and when the locations of vertices are below the base plane, the signed distance may be “−”. The simulation device may obtain the base plane corresponding to a desired bottom surface in the 3D clothes by moving the base plane upward in a up-vector direction to include a point where a signed distance value is minimum, that is, shifting the base plane upward to a point where the signed distance is minimum. For example, when signed distance values are “+1” and “−2”, the smaller number, −2, may be a value with a minimum signed distance.

As such, the simulation device may shift the base plane to a location of a vertex that includes the point where the signed distance from any vertex P on an end of the target portion and vertices located at the bottom from an arbitrary base plane generated by a normal vector is minimum.

The simulation device may transform target vertices on the 3D clothes into cylindrical coordinates based on the base plane. Here, since the roll-up does not involve twisting, an angular component θ in the cylindrical coordinate system 950 may be a constant. Accordingly, reflecting the roll-up in the target vertices may be simplified to a 2D transformation issue in the RZ plane, which is a virtual plane defined in the cylindrical coordinate system 950.

In other words, in the roll-up process, since theta is a constant, wherein the theta corresponds to an angle among components of the cylindrical coordinates, target vertices in the 2D pattern and/or 3D clothes affected by roll-up may move within the RZ plane. Here, r of the RZ plane may correspond to a width w from a center of the cylindrical coordinates to an arbitrary vertex v. In addition, z of the RZ plane may correspond to a height h in a normal direction of base planes.

The simulation device may simulate the 3D clothes in which roll-up is expressed, more easily through the virtual plane defined through the above-described process.

FIG. 10 is a flowchart illustrating a method of transforming target vertices into vertices in a virtual plane, according to an embodiment. Referring to FIG. 10, according to an embodiment, a simulation device may transform target vertices into vertices in a virtual plane through operations 1010 to 1040.

In operation 1010, the simulation device may project target vertices of the fold region determined in operation 530 onto a base plane. For example, the simulation device may transform all vertices in a set V of vertices affected by roll-up into the vertices in the base plane.

In operation 1020, the simulation device may determine a center point of a bounding box including target vertices projected onto the base plane in operation 1010 as a center point of the base plane. The center point of the bounding box including the projected target vertices may correspond to a center point of the cylinder.

In operation 1030, the simulation device may calculate a collision point between a ray emitted in a horizontal direction inward from the center point of the base plane determined in operation 1020 and a reference section corresponding to the number of folds of the fold region of roll-up. Here, the ray emitted in the horizontal direction from the center point of the base plane may be a ray emitted toward an inner portion of facing clothes in a polygon of a mesh of a rolled-up portion of the 3D clothes, in other words, a ray emitted toward the polygon of the mesh corresponding to the unfolded portion.

In operation 1040, the simulation device may transform the target vertices into the vertices in a virtual plane by moving the target vertices to locations separated by a width of a buffer region corresponding to each of the sections of the fold region from the collision point calculated in operation 1030. Here, the moving of the target vertices to locations separated by the width of the buffer region corresponding to each of the sections of the fold region from the collision point is to locate a portion folded by roll-up on an outer side of an unfolded portion, thereby preventing a pattern of the portion folded by roll-up and a pattern of the unfolded portion from overlapping.

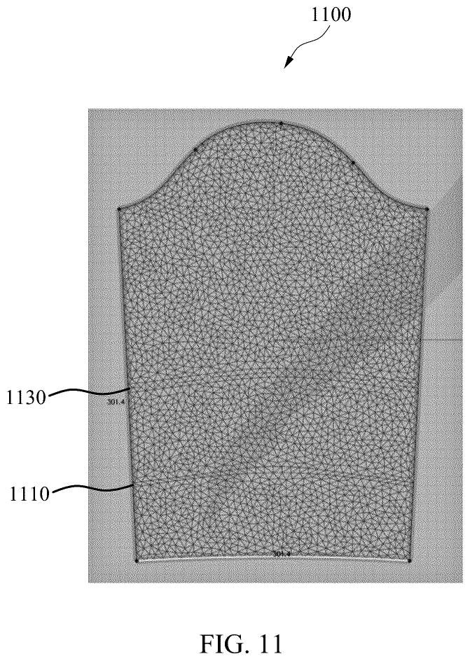

FIG. 11 is a diagram illustrating a result of re-meshing 2D vertices transformed into a virtual plane, according to an embodiment. Referring to FIG. 11, according to an embodiment, a diagram 1100 showing a 2D pattern in which resolution of a mesh is changed through re-meshing is illustrated.

The simulation device may perform re-meshing by moving at least one of locations and particle intervals of target vertices of a 2D pattern affected by roll-up among vertices of the 2D pattern so that at least one fold line 1110 or 1130 is reflected in the 2D pattern corresponding to a target portion (e.g., a sleeve) to be rolled up.

In order to add the at least one fold line 1110 or 1130 to the mesh of the 2D pattern, the simulation device may move the locations of the target vertices so that the target vertices, that is, one surface of polygons of the mesh is aligned with the at least one fold line 1110 or 1130. In addition, the simulation device may reduce the resolution of the mesh corresponding to the target vertices, that is, the particle intervals of the target vertices. The simulation device may finely change the particle intervals of a buffer region adjacent to the at least one fold line 1110 or 1130 and/or the target vertices at locations adjacent to the buffer region. As such, the mesh in which the particle intervals of the target vertices are finely changed may be referred to as a “fine mesh”.

By adjusting and re-meshing at least one of the locations and intervals of 2D vertices included in each of sections of a fold region, the simulation device may restore transformed 2D vertices to world coordinates corresponding to 3D clothes. Here, the 2D vertices included in each of the sections of the fold region may correspond to vertices transformed into the 2D vertices in a virtual plane.

The simulation device may solve an issue of insufficient mesh resolution resulting in uneven folded portions, by actually reflecting the at least one fold line 1110 or 1130 in the mesh of the 2D pattern. In addition, the simulation device may reduce operational complexity by performing a simulation using a coarse mesh before re-meshing, instead of a fine mesh, for a portion in which roll-up is not performed in 2D pattern, that is, a reference section that may not be folded.

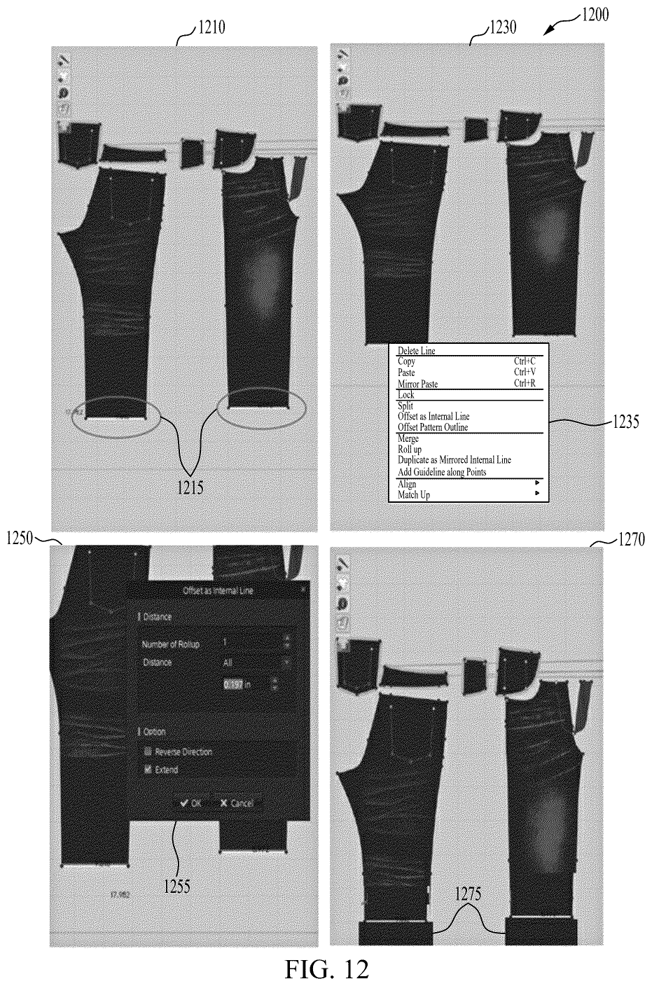

FIG. 12 is a diagram illustrating a process of performing a roll-up simulation through a user interface, according to an embodiment. Referring to FIG. 12, according to an embodiment, a diagram 1200 including a screen 1210 in which a user selects an outline of a target portion (e.g., hems of trousers) to be rolled up from among 2D patterns including 3D clothes, screens 1230 and 1250 in which a pop-up menu is displayed when the user activates a roll-up function by right-clicking after selecting the outline of the hems of the trousers, and a screen 1270 in which a result of a roll-up simulation is displayed by a value set by the pop-up menu is illustrated.

When the user selects a portion of the clothes (e.g., the hems of the trousers) 1215 on which the user desires to perform roll-up, as shown in the screen 1210, and then when the user performs a right-click, a pop-up menu 1235 including a roll-up function may be displayed on the screen, as shown in the screen 1230.

When the user selects the roll-up function included in the pop-up menu 1235, a user interface screen 1255 may be displayed to receive input of a fold interval of roll-up and the number of folds of roll-up, as shown in the screen 1250.

The simulation device may display a result of automatically simulating roll-up 1275 on the hems of the trousers, as shown in the screen 1270, according to the fold interval of roll-up and the number of folds of roll-up input in the user interface screen 1255.

According to an embodiment, the simulation device may automatically express the roll-up on the selected portion of the 3D clothes according to a preset fold interval of roll-up and/or number of folds of roll-up, without separate input from the user as shown in the user interface screen 1255, as the roll-up function is selected in the pop-up menu 1235.

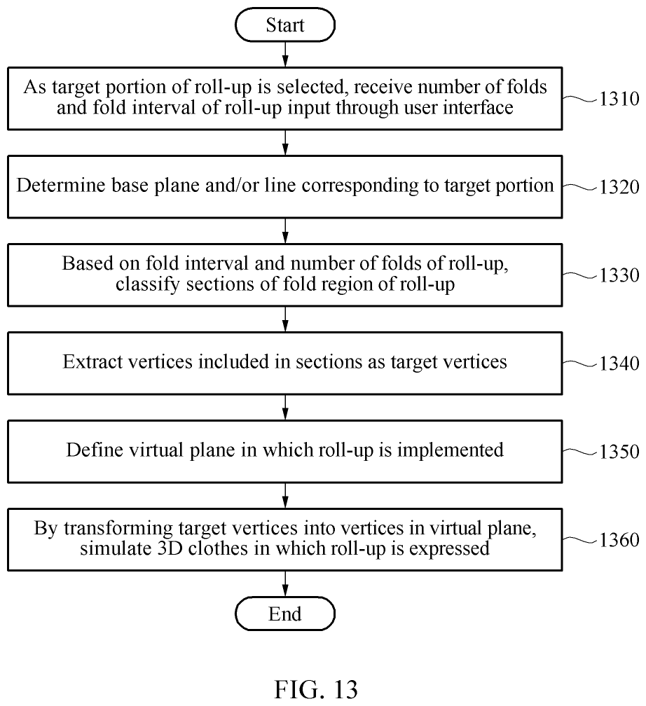

FIG. 13 is a flowchart illustrating a method of simulating roll-up, according to an embodiment. Referring to FIG. 13, according to an embodiment, a simulation device may simulate 3D clothes in which roll-up is expressed, through operations 1310 to 1360.

In operation 1310, as a target portion to be rolled-up in a 2D pattern and/or 3D clothes is selected, the simulation device may receive the number of folds of roll-up and a fold interval of roll-up through a user interface.

In operation 1320, the simulation device may determine a base plane and/or a base line corresponding to the target portion selected by a user in operation 1310.

In operation 1330, based on the fold interval of roll-up and the number of folds of roll-up from the base plane and/or the base line determined in operation 1320, the simulation device may classify sections of a fold region of roll-up in at least one 2D pattern and/or 3D clothes. The simulation device may, for example, in response to the number of folds n, classify the sections of the fold region into regions of (the number of folds of roll-up n×2)+1. The simulation device may assign indices corresponding to classified regions to target vertices.

The simulation device may set at least one fold line corresponding to the number of folds in at least one 2D pattern and/or 3D clothes. The simulation device may set a buffer region on at least one side adjacent to the at least one fold line. The simulation device may determine a region in which height and width are expanded as the sections of the fold region by reflecting the buffer region in a fold interval.

In operation 1340, the simulation device may extract vertices included in each of the sections of the fold region classified in operation 1330 as the target vertices.

In operation 1350, the simulation device may define a virtual plane in which roll-up is implemented.

In operation 1360, the simulation device may simulate 3D clothes in which roll-up is expressed by transforming the target vertices extracted in operation 1340 into vertices in the virtual plane defined in operation 1350.

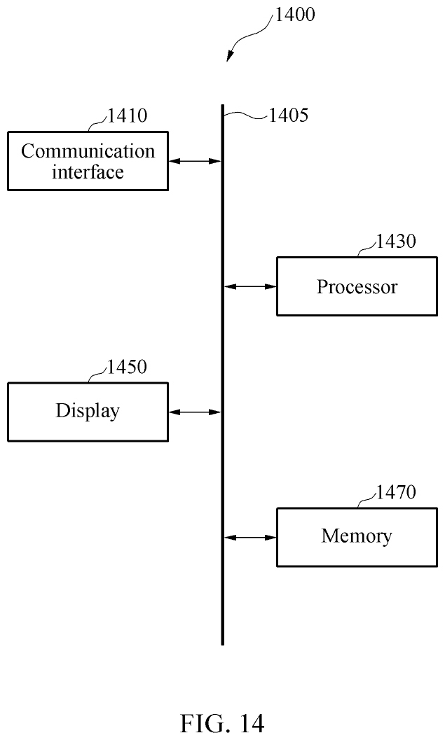

FIG. 14 is a block diagram illustrating a device for simulating roll-up, according to an embodiment. Referring to FIG. 14, according to an embodiment, a simulation device 1400 may include a user interface 1410, a processor 1430, a display 1450, and a memory 1470. The communication interface 1410, the processor 1430, the display 1450, and the memory 1470 may communicate each other via a communication bus 1405.

As a target portion to be rolled-up is selected by a user from among 2D patterns and/or 3D clothes displayed on the display 1450, the communication interface 1410 may receive the number of folds of roll-up and a fold interval of roll-up input through a user interface.

The processor 1430 may determine a base plane and/or a base line corresponding to the target portion. Based on the base plane and/or the base line, the processor 1430 may determine target vertices affected by the roll-up among vertices corresponding to the target portion. By transforming the target vertices into vertices in a virtual plane in which the roll-up is implemented, the processor 1430 may simulate the 3D clothes in which the roll-up is expressed.

The display 1450 may display the 2D patterns corresponding to the 3D clothes. In addition, the display 1450 may display the 3D clothes.

The memory 1470 may store the number of folds of roll-up and the fold interval of the roll-up received through the communication interface 1410. In addition, the memory 1470 may store the target vertices determined by the processor 1430 and/or the 3D clothes in which the roll-up simulated by the processor 1430 is expressed. The memory 1470 may store a variety of information generated in the processing process of the processor 1430 described above. In addition, the memory 1470 may store a variety of data and programs. The memory 1470 may include a volatile memory or a non-volatile memory. The memory 1470 may include a high-capacity storage medium such as a hard disk to store a variety of data.

In addition, the processor 1430 may perform at least one of the methods described with reference to FIGS. 1 to 13 or an algorithm corresponding to at least one of the methods. The processor 1430 may be a data processing device implemented by hardware including a circuit having a physical structure to perform desired operations. For example, the desired operations may include code or instructions in a program. The processor 1430 may be implemented as, for example, a central processing unit (CPU), a graphics processing unit (GPU), or a neural network processing unit (NPU). For example, the simulation device 1400 that is implemented as hardware may include, for example, a microprocessor, a CPU, a processor core, a multi-core processor, a multiprocessor, an application-specific integrated circuit (ASIC), and a field-programmable gate array (FPGA).

The processor 1430 may execute a program and control the simulation device 1400. Code of the program executed by the processor 1430 may be stored in the memory 1470.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs or DVDs; magneto-optical media such as optical discs; and hardware devices that are specially configured to store and perform program instructions, such as read-only memory (ROM), RAM, flash memory, and the like. Examples of program instructions include both machine code, such as produced by a compiler, and files containing higher-level code that may be executed by the computer using an interpreter. The above-described devices may be configured to act as one or more software modules in order to perform the operations of the above-described embodiments, or vice versa.

The software may include a computer program, a piece of code, an instruction, or some combination thereof, to independently or collectively instruct or configure the processing device to operate as desired. Software and/or data may be embodied permanently or temporarily in any type of machine, component, physical or virtual equipment, computer storage medium or device, or in a propagated signal wave capable of providing instructions or data to or being interpreted by the processing device. The software may also be distributed over network-coupled computer systems so that the software is stored and executed in a distributed fashion. The software and data may be stored by one or more non-transitory computer-readable recording mediums.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or rearranged or supplemented by other components or their equivalents.

What is claimed is:

1. A roll-up simulation method comprising:
receiving an input of a user for a target portion of roll-up in three-dimensional (3D) clothes;
determining a base plane corresponding to the target portion of the roll-up;
based on the base plane, determining target vertices affected by the roll-up among vertices corresponding to the target portion;
transforming the target vertices into vertices in which the roll-up is reflected; and
simulating the 3D clothes in which the roll-up is expressed.

2. The roll-up simulation method of claim 1, wherein
the base plane comprises a plane passing through an end of the target portion and perpendicular to a direction for the roll-up.

3. The roll-up simulation method of claim 1, wherein the determining of the base plane comprises:
determining at least one two-dimensional (2D) pattern corresponding to the target portion;
determining a base line in the at least one 2D pattern;
determining a midpoint of the base line;
determining an adjacent point located in a vertical direction from the midpoint into the at least one 2D pattern; and
setting an up-vector in a direction from the midpoint to the adjacent point.

4. The roll-up simulation method of claim 1, wherein the determining of the target vertices comprises:
based on a fold interval of the roll-up and a number of folds of the roll-up from the base plane, classifying the target portion into each of sections of a fold region of the roll-up; and
extracting vertices included in each of the sections of the fold region as the target vertices.

5. The roll-up simulation method of claim 4, wherein
the classifying of the target portion into the sections of the fold region comprises:
according to the fold interval and the number of folds from the base plane, determining a reference section corresponding to the number of folds among the sections of the fold region of roll-up, and
the extracting of the vertices as the target vertices comprises:
extracting vertices located below the reference section as the target vertices corresponding to each of the sections of the fold region.

6. The roll-up simulation method of claim 4, wherein the classifying of the target portion into the sections of the fold region comprises:
according to the fold interval and the number of folds from the base plane, assigning an index corresponding to the sections of the fold region to the target vertices.

7. The roll-up simulation method of claim 4, wherein the classifying of the target portion into the sections of the fold region comprises classifying the target portion into the sections of the fold region according to a preset formula.

8. The roll-up simulation method of claim 4, wherein the classifying of the target portion into the sections of the fold region comprises:
setting at least one fold line and a buffer region corresponding to the number of folds; and
determining the sections of the fold region by reflecting the buffer region in the fold interval.

9. The roll-up simulation method of claim 8, wherein the setting of the at least one fold line comprises re-meshing by moving at least one of locations and particle intervals of the target vertices.

10. The roll-up simulation method of claim 8, wherein the buffer region increases as a number of the sections of the fold region increases.

11. The roll-up simulation method of claim 4, wherein the simulating of the 3D clothes comprises transforming the target vertices included in each of the sections of the fold region into the vertices in which the roll-up is reflected.

12. The roll-up simulation method of claim 1, wherein the transforming of the target vertices into the vertices in which the roll-up is reflected comprises:
defining a virtual plane comprising at least one of the target vertices and a z-axis perpendicular to the base plane; and
transforming at least one of the target vertices into vertices in the virtual plane.

13. The roll-up simulation method of claim 1, wherein the simulating of the 3D clothes comprises simulating the 3D clothes by restoring the transformed vertices to world coordinates corresponding to the 3D clothes.

14. The roll-up simulation method of claim 12, wherein the defining of the virtual plane comprises:
projecting the target vertices onto the base plane;
determining a center point of a bounding box including the target vertices projected onto the base plane; and
determining the z-axis based on the center point.

15. The roll-up simulation method of claim 12, wherein the transforming of the at least one of the target vertices into the vertices in the virtual plane comprises:
calculating a displacement corresponding to the at least one of the target vertices in the virtual plane, based on a height and a width corresponding to the number of folds and the fold interval of the roll-up.

16. A computing device comprising:
at least one processor; and
a memory configured to store a plurality of instructions, wherein the plurality of instructions, when executed by the at least one processor, causes the computing device to perform:
receiving an input of a user for a target portion of roll-up in three-dimensional (3D) clothes;
determining a base plane corresponding to the target portion of the roll-up;
based on the base plane, determining target vertices affected by the roll-up among vertices corresponding to the target portion;
transforming the target vertices into vertices in which the roll-up is reflected; and
simulating the 3D clothes in which the roll-up is expressed.
